(19) United States
(12) Patent Application Publication
(10) Pub. No.: US 2014/0353578 A1
(43) Pub. Date: Dec. 4, 2014

(54) LIGHT-EMITTING DEVICE

(71) Applicant: EPISTAR CORPORATION, Hsinchu (TW)

(72) Inventor: Lien Wei CHIEH, Hsinchu (TW)

(21) Appl. No.: 13/909,231

(22) Filed: Jun. 4, 2013

(51) Int. Cl. H01L 33/06; H01L 33/00

(52) U.S. Cl. CPC H01L 33/06; H01L 33/002
USPC 257/13

(57) ABSTRACT

A light emitting device disclosed herein comprises a substrate, a buffer stack formed on the substrate, a tunneling junction stack formed on the buffer stack comprising an un-doped layer, a light-emitting stack formed on the tunneling junction stack, and a contact stack formed on the light emitting stack. The structure of the light emitting device disclosed also reduce the energy band bending arisen from the lattice mismatch and improve the epitaxy quality of the stacks.

### TECHNICAL FIELD

This present application relates to a light-emitting device, and more particularly to a light-emitting device having a tunneling junction to improve light emitting efficiency.

### BACKGROUND OF THE DISCLOSURE

The light-emitting diodes (LEDs) of the solid-state lighting elements have the characteristics of low heat generation, long operational life, small volume, quick response and the light emitted with a stable wavelength range, so the LEDs have been widely used in various applications. Recently, efforts have been devoted to improve the luminance of the LED in order to apply the device to the lighting domain, and further achieve the goal of energy conservation and carbon reduction.

One factor hindering the luminance of the LED is the lattice mismatch between layers of the LED. The lattice mismatch not only affects quality of the epitaxy layers but also induces piezoelectric polarization effect which causes energy band bending. To be more specific, the piezoelectric polarization effect induces energy band bending by the internal electric field resulted from neighboring layers. Once the internal electric field affects the energy band of the active layer and causes the energy band bending, the electron confinement of the active layer is weakened and reduces the light emitting efficiency.

### SUMMARY OF THE DISCLOSURE

The present disclosure provides a light emitting device which comprises a substrate, a buffer stack formed on the substrate, a tunneling junction stack formed on the buffer stack comprising a first un-doped layer, a light-emitting stack formed on the tunneling junction stack, and a contact stack formed on the light emitting stack.

### BRIEF DESCRIPTION OF THE DRAWINGS

FIG. 1 shows an embodiment of the present disclosure.

FIG. 2 shows an embodiment of the tunneling junction stack of the present disclosure.

FIGS. 3a-3b show embodiments of the present disclosure.

FIG. 4 shows an embodiment of the present disclosure.

FIGS. 5a-5g depict process of fabrication in accordance with an embodiment according to the present disclosure.

FIGS. 6a-6b show an embodiment of the present disclosure.

### DETAILED DESCRIPTION OF THE PREFERRED EMBODIMENTS

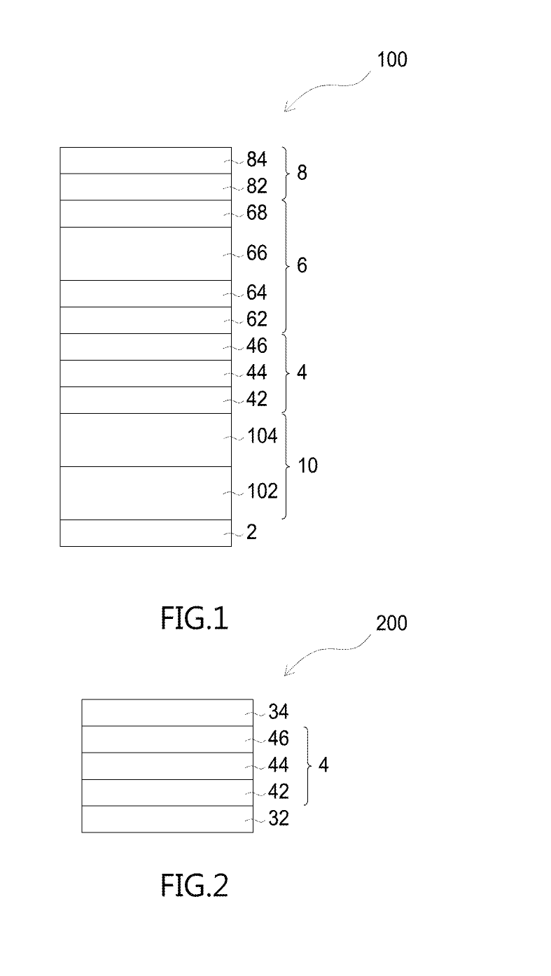

FIG. 1 shows an embodiment of the present disclosure. A light emitting device 100 comprises a substrate 2, a buffer stack 10, a tunneling junction stack 4, a light emitting stack 6, and a contact stack 8. The light emitting stack 6 comprises a lower semiconductor layer 62, a carrier blocking layer 64, an active layer 66, and an upper semiconductor layer 68. To be more specific, the lower semiconductor layer 62 and the upper semiconductor layer 68 can act as cladding layers or confinement layers. The light emitting device 100 is a semiconductor device and the active layer 66 emits an incoherent light. In this embodiment, the substrate 2 is made of silicon while the lower semiconductor layer 62 and the upper semiconductor layer 68 are composed of a gallium nitride. In this embodiment, the lower semiconductor layer 62 is a p-type semiconductor layer, the upper semiconductor layer 68 is an n-type semiconductor layer and the active layer 66 is a multi-quantum well (MQW) layer.

Referring to FIG. 1, a buffer stack 10 is formed on the substrate 2 before forming the light emitting stack 6 on the substrate 2. The substrate 2 can be a growth substrate. The buffer stack 10 is formed to reduce the lattice mismatch between the substrate 2 and the light emitting stack 6. The buffer stack 10 is composed of semiconductor layers comprising an un-doped layer 102 on the substrate 2 and a doped layer 104 on the un-doped layer 102. The un-doped layer 102 is formed without doping impurities but it is possible that some impurities are diffused into the un-doped layer 102 when forming the doped layer 104. The un-doped layer 102 is formed on the substrate 2 before the doped layer 104 for a better epitaxy layer quality. Furthermore, the doped layer 104 is doped with n-type impurities because the n-type semiconductor layer has a characteristic of better current spreading than the un-doped layer and the p-type semiconductor layer. Moreover, the n-type semiconductor layer has a characteristic of better current spreading in a horizontal direction compared to the p-type semiconductor layer. In this embodiment, the materials of un-doped layer 102 and the doped layer 104 comprise III-V materials, such as gallium nitride.

As mentioned above, when the doped layer 104 is an n-type semiconductor layer and the lower semiconductor layer 62 is a p-type semiconductor layer, the current transmission is obstructed. Therefore a tunneling junction stack 4 is formed to reduce the obstruction. The tunneling junction stack 4 is composed of an n-type semiconductor layer 42 connected to the doped layer 104, a p-type semiconductor layer 46 connected to the lower semiconductor layer 62 and an un-doped layer 44 between the n-type semiconductor layer 42 and the p-type semiconductor layer 46. The un-doped layer 44 is designed to be formed without impurities but some impurities may accidentally diffuse into the un-doped layer 44. The tunneling junction stack 4 improves current transmission within the light emitting device 100. In this embodiment, the tunneling junction stack 4 is made of III-V material, the materials of n-type semiconductor layer 42 and the p-type semiconductor layer 46 comprise GaN and the material of the un-doped layer 44 comprises (In_{y}Ga_{1-y})N (0.2≦y≦1). Besides, the impurity of the above n-type layer can be Si and the impurity of the above p-type layer can be Mg or Zn.

Although the tunneling junction stack 4 can improve current transmission, the forward voltage is also increased with an additional layer added in the structure of the light emitting device 100. Referring to FIG. 2, to study the influence of the tunneling junction stack 4, contact pads 32 and 34 are separately connected to the n-type semiconductor layer 42 and the p-type semiconductor 46 to form a test device 200. The contact pads 32 and 34 can receive bias current so the voltage of the tunneling junction stack 4 can be measured. The test device 200 is configured to simulate the situation of the tunneling junction stack 4 in the light emitting device 100 operated under a bias current. Besides, the impurity concentration of the n-type semiconductor layer 42 is larger than the n-type doped layer 104, and the impurity concentration of the p-type semiconductor layer 46 is also larger than the p-type lower semiconductor layer 62 so the electrical connection between layers is improved. In this embodiment, the concentration of the n-type semiconductor layer 42 is 5*10¹⁹ cm⁻³ and the concentration of the p-type semiconductor 46 is 3*10¹⁹ cm⁻³ thus the voltage of the tunneling junction stack 4 is 0.012 (V) when a current with a density of 20 A/cm² is applied to the structure in FIG. 2. In other words, the voltage drop at two ends of the test device 200 equals to 0.012 V while a current with a density of 20 A/cm² passing through the test device 200. The 0.012 V can contribute to the increase of forward voltage of the light emitting device 100 while the tunneling junction stack 4 is adopted in the light emitting device 100. In another embodiment, the concentration of the n-type semiconductor layer 42 is larger than 5*10¹⁹ cm⁻³ and the concentration of the p-type semiconductor 46 is larger than 3*10¹⁹ cm⁻³. In this embodiment, the thickness of each layer of the tunneling junction stack 4 is also modified such that the thickness of the un-doped layer 44 is smaller than the thickness of the n-type semiconductor layer 42 or the thickness of the p-type semiconductor layer 46.

As mentioned above, the lattice mismatch between layers results in piezoelectric effect which also causes an internal electric field. The internal electric field further bends the energy band of neighboring layers. Once the effect is applied to the active layer of the LED, the light emitting efficiency is then reduced. A carrier blocking layer is formed between a p-type semiconductor layer and an active layer to block the electron from the n-type semiconductor layer injecting to the p-type semiconductor layer thus the carrier blocking layer has a higher energy band gap than the p-type semiconductor layer. It also implies the lattice constant of the carrier blocking layer is different from the lattice constant of the p-type semiconductor layer. The piezoelectric effect is then occurs due to the lattice constant mismatch and induces an internal electric field. In order to prevent the internal electric field bending the energy band of the active layer, a stack arrangement is provided.

In this embodiment, the carrier blocking layer 64 is formed on the lower semiconductor layer 62 and an active layer 66 is then formed on the carrier blocking layer 64 to prevent the internal electric field from affecting the active layer 66. In this embodiment, the lower semiconductor layer 62 and the carrier blocking layer 64 are p-type semiconductor layers while the upper semiconductor layer 68 is n-type. Furthermore, the internal electric field directs in a direction from the carrier blocking layer 64 towards the lower semiconductor layer 62 and also toward the substrate 2. Thus, the internal electric field arisen between the lower semiconductor layer 62 and the carrier blocking layer 64 does not pass the active layer 66 so the energy band of the active layer 66 is not bent and the light emitting efficiency is not reduced. In this embodiment, the carrier blocking layer 64 and the lower semiconductor layer 62 are III-V semiconductor layers. To be more specific, the material of the carrier blocking layer 64 comprises AlₓGa₁₋ₓN(x>0) and the material of the lower semiconductor layer 62 comprises GaN. In another embodiment, the material of the lower semiconductor layer 62 comprises AlGaN or AlInGaN.

Referring to FIG. 1, a contact stack 8 is formed on the light emitting stack 6. The contact stack 8 improves the effect of current spreading in a direction perpendicular to the direction of forming the buffer stack 10 on the substrate 2. The contact stack 8 comprises a first contact layer 82 and a second contact layer 84 formed above the first contact layer 82. In this embodiment, the materials of the first contact layer 82 and the second contact layer 84 comprise III-V semiconductor, such as gallium nitride. The first contact layer 82 is an un-doped layer while the second contact layer 84 comprises high impurity doping concentration. Namely, the impurity concentration of the second contact layer 84 is greater than that of the first contact layer 82 such that the resistivity of the first contact layer 82 is greater than the second contact layer 84. Besides, the impurity concentration of the upper semiconductor layer 68 is also greater than that of the first contact layer 82. Once a current is applied to the light emitting device 100, the current flows in a first direction from the second contact layer 84 toward the substrate 2 wherein the speed of current moving within the second contact layer 84 is greater than within the first contact layer 82. While the current reaches the interface between the first contact layer 82 and the second contact layer 84, the current tends to move toward the direction of smaller resistivity. Namely, the current tends to move in a second direction perpendicular to the first direction within the second contact layer 84 more than moving in a first direction. So, the current is distributed more widely in a second direction which implies more area of the active layer 66 receives current so the light emitting efficiency is improved.

In order to prevent piezoelectric effect, in the embodiment, the lower semiconductor layer 62, which is p-type, is formed below the active layer 66, the upper semiconductor layer 68 is an n-type semiconductor layer and the second contact layer 84 above the upper semiconductor layer 68 is an n-type semiconductor layer. Moreover, the doped layer 104 is also an n-type semiconductor.

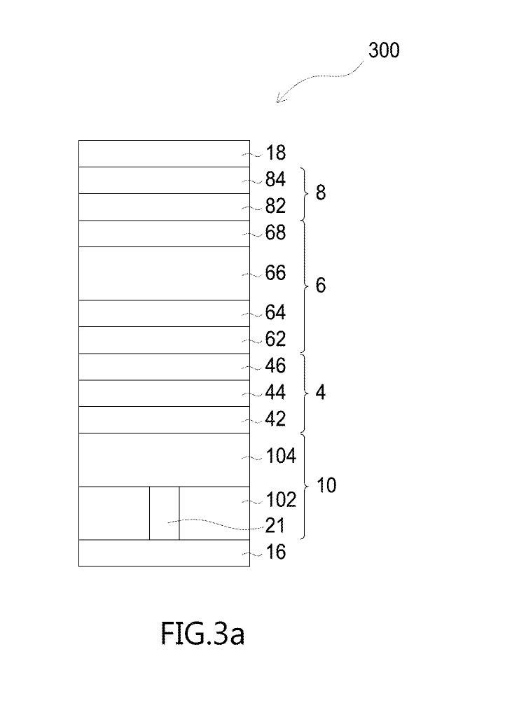

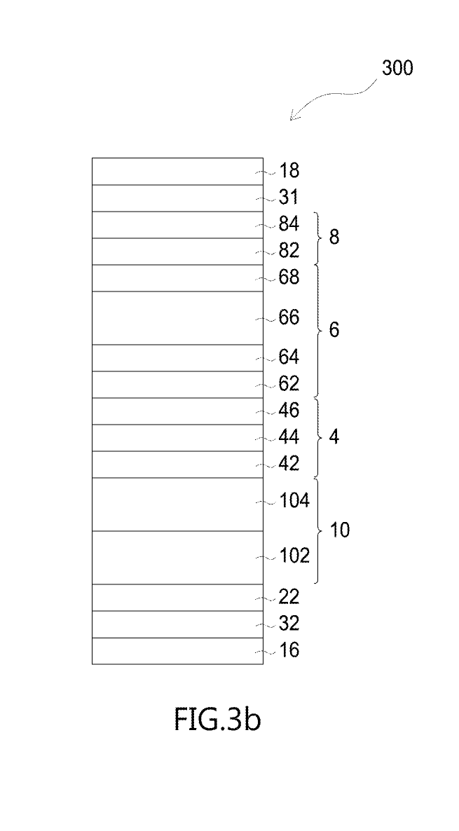

Both the doped layer 104 and the second contact layer 84 are designed for forming Ohmic contacts with contact pads 16 and 18. Referring to FIG. 3a, the through hole 21 is formed to pass the un-doped layer 102 and is filled with a conductive material to form an Ohmic contact between the second contact pad 16 and the doped layer 104. The second contact pad 16 is electrically connected to the doped layer 104 by the through hole. On the other side, the first contact pad 18 is formed on the contact stack 8 to form an Ohmic contact with the second contact layer 84. In another embodiment, the second contact pad 16 is formed after an insulating layer is removed from the un-doped layer 102.

Referring to FIG. 3b, based on the requirement of the application, a carrier 22 is formed on the un-doped layer 102. The material of the carrier 22 can be conductive material, transparent material, and reflective material. The conductive material can be semiconductor, transparent conductive oxide, metal, and metal alloy. The transparent material can be GaN, sapphire, SiC, GaN, or AlN. The reflective material can be metal, dielectric material, or the combination thereof. Moreover, the carrier 22 can be made of various shapes to redirect the light emitted based on the requirement of the application.

Furthermore, a first current spreading layer 31 is formed between the first contact pad 18 and the contact stack 8 and a second current spreading layer 32 is formed between the second contact pad 16 and the buffer stack 10 as shown in FIG. 3b. The current spreading layers can be transparent conductive layers and the materials of the current spreading comprises conductive metal oxide, such as ITO and ZnO or conductive semiconductor layer such as the semiconductor layer having a high doping concentration phosphides or nitride compound.

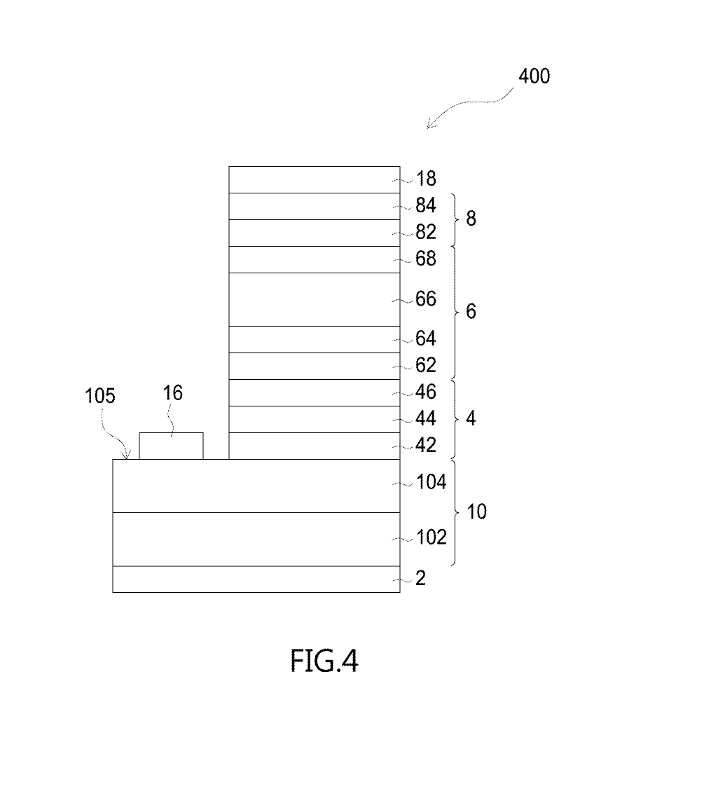

In another embodiment as illustrated in FIG. 4, part of the light emitting device 100 is removed to expose a part of the buffer stack 10. The buffer stack 10 has a top surface 105 between the buffer stack 10 and the tunneling junction stack 4. The top surface 105 of the buffer stack 10 has a first region covered by the tunneling junction stack 8 and a second region not covered by the tunneling junction stack 8. The first contact pad 18 is formed on the contact stack 8 on the first region of the top surface 105. The second contact pad 16 is formed on the second region of the top surface 105. Thus an Ohmic contact is formed at the interface between the first contact pad 18 and the contact stack 8 and an Ohmic contact is formed at the interface between the second contact pad 16 and the buffer stack 10.

To improve the light emitting efficiency, other layers can be formed between, above, below and/or surround the layers of the light emitting device during the manufacturing process. In an embodiment, a reflective layer (not shown in the figure) is formed between the active layer 66 and the substrate 2 or formed on the side walls of the light emitting device 100 to redirect light from the active layer 66. The reflective layer can be multi-layers such as omnidirectional reflector (ODR) or distributed Bragg reflector (DBR). Besides, current spreading layers (not shown in the figure) are formed between the first contact pad 18 and the contact stack 8 and/or between the second contact pad 16 and the buffer stack 10. The current spreading layers can be made of transparent conductive material, such as ITO. In another embodiment, a window layer (not shown in the figure) is applied between the contact stack 8 and the first contact pad 18. The window layer not only redirects the direction of light but also increases the amount of emitted light.

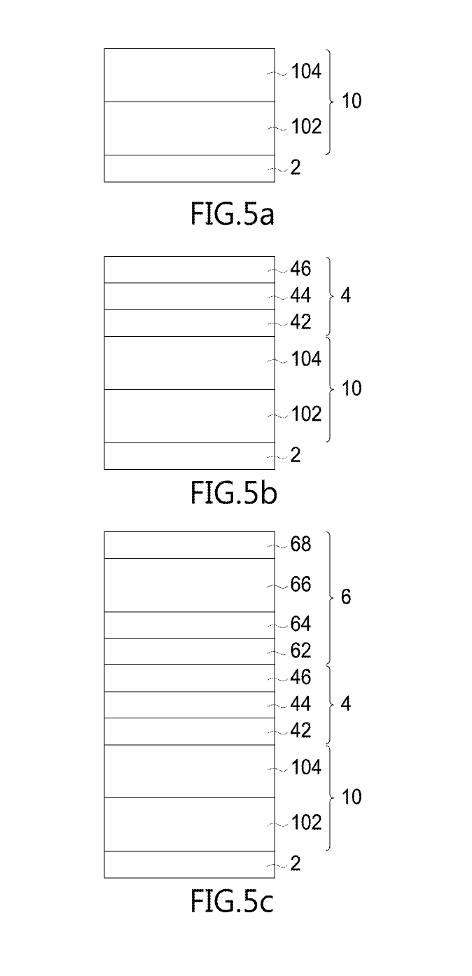

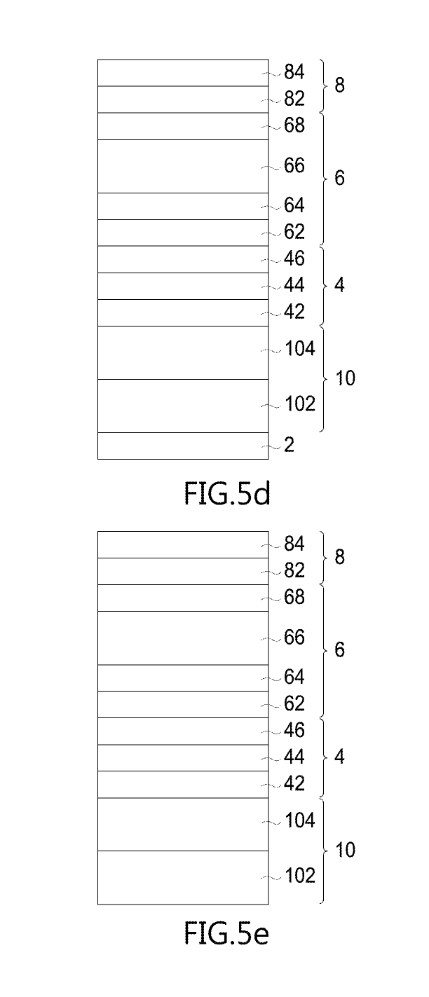

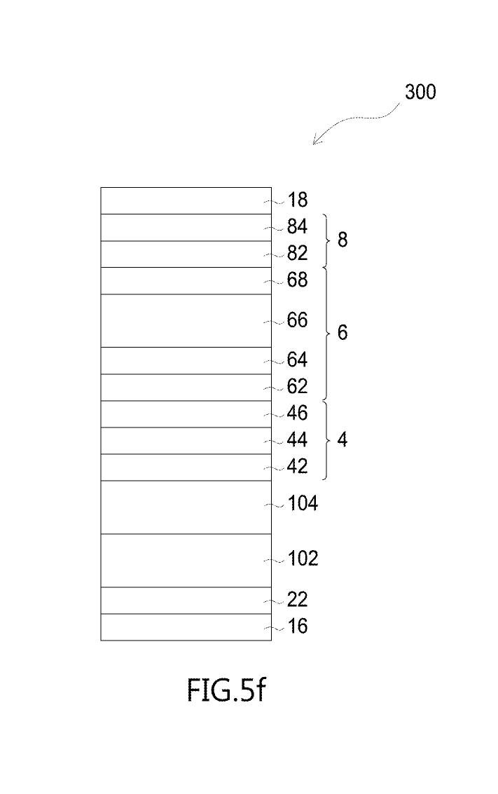

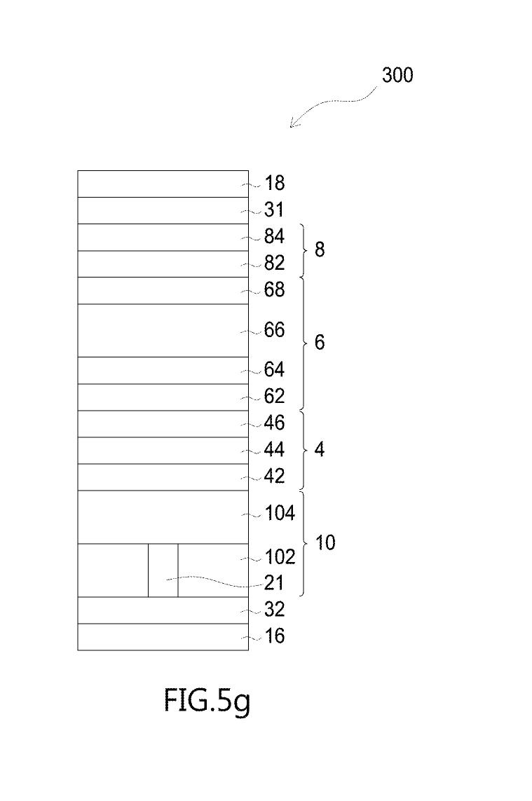

Some processes for changing the direction of light transmission are performed. For example, a surface roughing process is applied to the substrate 2, to the buffer stack 10, or to the contact stack 8 to enhance the light scattering and/or to decrease the amount of light absorbed within the light emitting device 100 due to total internal reflection (TIR). The roughing process can also be applied to the side walls of the light emitting device to improve light diffraction. The roughed surface can be realized by physically mechanical process comprising sand blasting or by chemical process comprising wet etching and electrical chemical process. FIGS. 5a-5g depict a process flow in accordance with an embodiment of the present disclosure. A substrate 2 and a buffer stack 10 on the substrate 2 are formed as illustrated in FIG. 5a. In the embodiment, the substrate 2 can be a growth substrate. Besides, the buffer stack 10 comprises an un-doped layer 102 and a doped layer 104 which is an n-type semiconductor. The buffer stack 10 can reduce the lattice mismatch between the substrate 2 and the epitaxy layers formed above later for a better quality of the epitaxy layers. Referring to FIG. 5b, a tunneling junction stack 4 is formed on the buffer stack 10. The tunneling junction stack 4 comprises an n-type semiconductor layer 42, a p-type semiconductor layer 46 and an un-doped layer 44. The tunneling junction stack 4 is made of III-V semiconductor material. To be more specific, the materials of the n-type semiconductor layer 42 and the p-type semiconductor layer 46 comprise GaN and the material of the un-doped layer 44 comprises (In_{y}Ga_{1-y})N (0.2≦y≦1). In this embodiment, the thickness of the un-doped layer 44 is smaller than the thickness of the n-type semiconductor layer 42 or the thickness of the p-type semiconductor layer 46; the impurities concentrations of the n-type semiconductor layer 42 is larger than 5*10¹⁹ cm⁻³ and the impurities concentrations of the p-type semiconductor 46 is larger than 3*10¹⁹ cm⁻³.

A light emitting stack 6 is then formed on the tunneling junction stack 4 as shown in FIG. 5c. The light emitting stack 6 comprises a lower semiconductor layer 62, a carrier blocking layer 64, an active layer 66 and an upper semiconductor layer 68. In this embodiment, both the lower semiconductor layer 62 and the carrier blocking layer 64 are p-type semiconductor layers and the upper semiconductor layer 68 is an n-type semiconductor layer. The arrangement described above can prevent energy band of the active layer 66 from bending caused by the internal electric field arisen from piezoelectric effect. In this embodiment, the impurity concentration of the lower semiconductor layer 62 is smaller than the p-type semiconductor 46. In this embodiment, the carrier blocking layer 64 and the lower semiconductor layer 62 are III-V semiconductor layers. To be more specific, the material of the carrier blocking layer 64 comprises AlₓGa₁₋ₓN(x>0) and the material of the lower semiconductor layer 62 comprises GaN. In another embodiment, the material of the lower semiconductor layer 62 comprises AlGaN or AlInGaN.

Referring to FIG. 5d, a contact stack 8 is formed on the upper semiconductor layer 68. The contact stack 8 includes a first contact layer 82 and a second contact layer 84. In this embodiment, the first contact layer 82 is an un-doped layer while the second contact layer 84 comprises high impurity doping concentration. In this embodiment, the structure of the contact stack 8 further improves current spreading. The current flows in a first direction from the second contact layer 84 toward the substrate 2. The speed of current moving within the second contact layer 84 is greater than within the first contact layer 82. Since the current tends to move toward the direction of smaller resistivity, the current tends to move in a second direction perpendicular to the first direction within the second contact layer 84 more than moving in a first direction so the current is distributed more widely in a second direction and more area of the active layer 66 receives current. The light emitting efficiency is improved accordingly.

Referring to FIGS. 5d-5f, the substrate 2 is removed and a carrier 22 is formed on the buffer stack 10 according to the requirement of the application. The contact pad 18 is formed on the contact stack 8 while the contact pad 16 is formed on the carrier 22.

In another embodiment, a through hole 21 is formed in the un-doped layer 102 and filled with conducting materials to form an Ohmic contact between the doped layer 104 and the contact pad 16 as shown in FIG. 5g. Besides, transparent conductive layers such as ITO layer are applied as current spreading layers to improve current spreading. The first current spreading layer 31 is formed between the contact pad 18 and the contact stack 8. The second current spreading layer 32 is formed between the contact pad 16 and the un-doped layer 102.

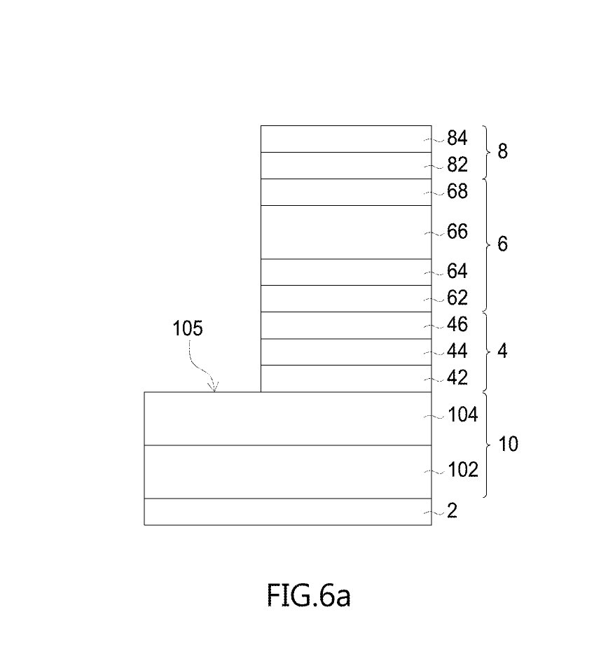

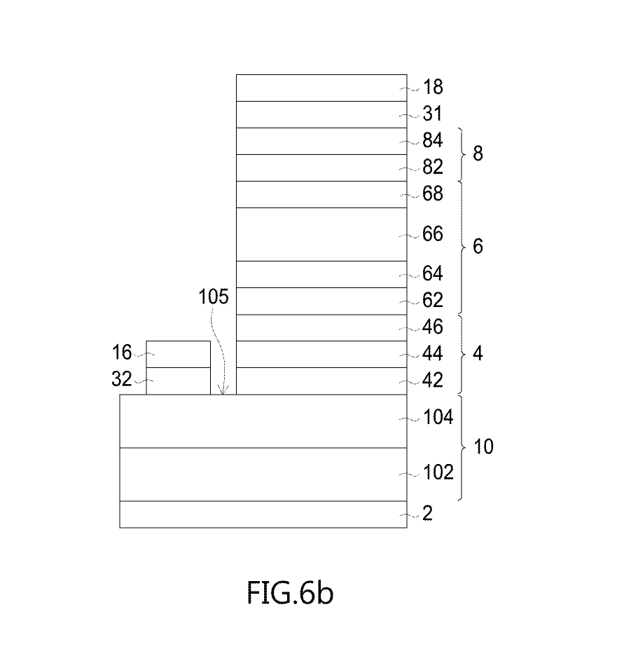

FIGS. 6a-6b show another embodiment of the present disclosure. After the structure depicted in FIG. 5d is completed, removing a portion of the contact stack 8, the light emitting stack 6, and the tunneling junction stack 4 to expose a part of the buffer stack 10. Thus the top surface 105 of the buffer stack 10 has a first region covered by the tunneling junction stack 8 and a second region which is exposed and not covered by the tunneling junction stack.

The contact pad 18 is formed on the contact stack 8. The contact pad 16 is formed on the second region of the top surface 105 as illustrated in FIG. 6b. Besides, a transparent conductive layer, such as ITO, is used to improve current spreading. The first transparent conductive layer 31 is formed between the contact pad 18 and the contact stack 8. The second transparent conductive layer 32 is formed between the contact pad 16 and the second region.

Not only the structures of the light emitting device shown above, some processes for changing or mixing colors are applied in order to meet different lighting application. For example, a process of forming a cover on the light emitting device 400 is adopted to change the characteristic of the light emitted by the light emitting device. In an embodiment, the cover comprises wavelength tuning material to change the wavelength wherein the wavelength tuning material comprises phosphor. In another embodiment, the wavelength tuning material is formed on the light emitting device directly.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting device, comprising:
a substrate;
a buffer stack formed on the substrate;
a tunneling junction stack formed on the buffer stack comprising
a first un-doped layer;
a light-emitting stack formed on the tunneling junction stack; and
a first contact layer formed on the light emitting stack.

2. The light emitting device to claim 1, further comprising a second contact layer having a resistivity greater than the first contact layer formed between the light emitting stack and the first contact layer.

3. The light-emitting device to claim 2, wherein the buffer stack comprises a second un-doped layer on the substrate and a first semiconductor layer with a first conductivity type on the second un-doped layer.

4. The light-emitting device to claim 3, wherein the tunneling junction stack further comprises a second semiconductor layer with the first conductivity type below the first un-doped layer and a third semiconductor layer with a second conductivity type above the first un-doped layer.

5. The light-emitting device to claim 4, wherein an impurity concentration of the second semiconductor layer is larger than that of the first semiconductor layer.

6. The light-emitting device to claim 3, wherein the light-emitting stack comprises:
a fourth semiconductor layer with the second conductivity type on the tunneling junction stack;
an active layer on the fourth semiconductor layer; and
a fifth semiconductor layer with the first conductivity type on the active layer.

7. The light-emitting device to claim 6, wherein the first conductivity type is n-type and the second conductivity type is p-type.

8. The light-emitting device to claim 6, wherein an impurity concentration of the third semiconductor layer is larger than that of the fourth semiconductor layer.

9. The light-emitting device to claim 6, wherein the light-emitting stack further comprises a carrier blocking layer formed between the fourth semiconductor layer and the active layer, and an energy band gap of the carrier blocking layer is greater than that of the fourth semiconductor layer.

10. The light-emitting device to claim 9, wherein the carrier blocking layer comprises AlₓGa₁₋ₓN, x>0.

11. The light-emitting device to claim 1, wherein the buffer stack comprises a top surface between the buffer stack and the tunneling junction stack comprising a first region covered by the tunneling junction stack and a second region not covered by the tunneling junction stack.

12. The light-emitting device to claim 11, further comprising a first electrode pad on the first contact layer and a second electrode pad on the second region.

13. The light-emitting device to claim 1, wherein the first un-doped layer comprises (In_{y}Ga_{1-y})N, 0.2≦y≦1.

14. The light-emitting device to claim 2, wherein an impurity concentration of the first contact layer is greater than that of the second contact layer.

15. The light emitting device to claim 1, further comprising a current spreading layer formed on the first contact layer.

16. The light-emitting device to claim 6, wherein an impurity concentration of the fifth semiconductor layer is greater than that of the second contact layer.

17. The light-emitting device to claim 3, further comprising a first electrode pad on the current spreading layer and a second electrode pad on a surface of the first semiconductor layer opposite to the light-emitting stack.

18. The light-emitting device to claim 4, wherein a thickness of the first un-doped layer is smaller than that of the second semiconductor layer or the third semiconductor layer.

19. The light-emitting device to claim 4, wherein an impurity concentration of the second semiconductor layer is not less than 5*10¹⁹ cm⁻³ and an impurity concentration of the third semiconductor layer is not less than 3*10¹⁹ cm⁻³.

20. The light-emitting device to claim 6, wherein the conductivity type of the carrier blocking layer is the same as that of the fourth semiconductor layer.
